(19) United States
(12) Patent Application Publication
(10) Pub. No.: US 2001/0050039 A1
(43) Pub. Date: Dec. 13, 2001

(54) Method of forming a thin film using atomic layer deposition method

(76) Inventor: Chang-Soo Park, Seoul (JP)

Correspondence Address: Timothy J. Keefer, Wildman, Harrold, Allen & Dixon, 225 West Wacker Drive, Chicago, IL, 60606, US

(21) Appl. No.: 09/874,686

(22) Filed: Jun. 5, 2001

(30) Foreign Application Priority Data
Jun. 7, 2000 (KR) 2000-31040

(51) Int. Cl. C30B 23/00; C30B 25/00; C30B 28/12; C30B 28/14

(52) U.S. Cl. 117/102; 117/84

(57) ABSTRACT

The present invention discloses a method of fabricating a thin film using an atomic layer deposition, the method including: a first step of disposing a silicon substrate in a reaction chamber; a second step of introducing a first reactive gas and a carrier gas into the reaction chamber during a first period such that the first reactive gas is chemically adsorbed on the silicon substrate, wherein the reaction chamber is set to a first pressure during the first period; a third step of introducing a second reactive gas into the reaction chamber during a second period such that the second reactive gas is chemically adsorbed on the silicon substrate and discharges a residual portion of the first reactive gas out of the reaction chamber, wherein the reaction chamber is set to a lower second pressure than the first pressure during the second period; and further introducing the second reactive gas into the reaction chamber for a third period such that the second reactive gas is further chemically adsorbed on the silicon substrate, wherein the reaction chamber is set to a higher third pressure than the first pressure during the third period.

This application claims the benefit of Korean Patent Applications No. 2000-31040 filed on Jun. 7, 2000, which is hereby incorporated by reference as if fully set forth herein.

### BACKGROUND OF THE INVENTION

1. Field of the Invention

The present invention relates to a thin film technology using an atomic layer deposition (ALD) method, and more particularly to a thin film technology using an ALD method having a shortened processing cycle.

2. Discussion of the Related Art

Generally, a thin film is widely used for dielectrics of a semiconductor device, a transparent conductive element of a liquid crystal display device, a passivation layer of a light-emitting device, and the like. Various technologies well known in the art exist for applying thin films to substrates. Among the more established technologies available for applying thin films, evaporation method, chemical vapor deposition (CVD), and atomic layer deposition (ALD) are often used.

The CVD implements a better productivity than the ALD. However, in case of the CVD method, source gases including chlorine gas and the like are used for forming the thin film such that impurities having chlorine remains in the thin film. Therefore, additional processes such as a plasma treatment are needed to exclude the impurities of the thin film. Recently, the CVD is often performed under a low pressure to achieve desired step coverage and uniform thickness as well as to avoid contamination due to an atmospheric pressure condition. However, the low pressure causes a low deposition rate such that the productivity of the CVD method is declined. To increase the deposition rate, high partial pressure and high reaction temperature are needed for reactive gases. However, when the partial pressure of a reactive gas increases, the reactive gas reacts with other non-reacting gases such that contaminating particles are produced as a side product. In addition, the high reaction temperature causes a distortion of other films disposed under the thin film on fabrication.

Compared with the CVD method, the ALD method has a relatively low productivity. However, in case of the ALD, thin films having superior step coverage and uniform composition are formed at a relatively low temperature. In addition, thin films by the ALD method have a low impurity concentration.

FIG. 1 is a graph illustrating a method of forming a thin film using a conventional ALD technology according to the U.S. Pat. No. 4,413,022.

During a first period “ct1”, a first reactive gas is introduced into a reaction chamber and remains therein under a first pressure “CP1”. At this point, a silicon (Si) substrate where a thin film will be formed is already disposed in the reaction chamber. Then, inflow of the first reactive gas is stopped, and an inert gas, usually Ar or He, is introduced into the reaction chamber for a second period “ct2”. The inert gas prevents the first reactive gas from being over-adsorbed on the silicon (Si) substrate, and discharges a residual non-reacting gas out of the reaction chamber. Thereafter, a reduction gas, a second reactive gas, is introduced into the reaction chamber during a third period “ct3”, and remains therein under a second pressure “CP2”. Then, inflow of the second reactive gas is stopped, and another inert gas, also usually Ar or He, is introduced into the reaction chamber for a fourth period “ct4”. This inert gas discharges another residual non-reacting gas out of the reaction chamber.

At this point, the first and second pressures “CP1” and “CP2” beneficially have low values such that the silicon substrate is exposed to the first and second reactive gases for just a minimum time. In addition, the inert gases should be charged into the reaction chamber for a sufficient time to discharge the remaining non-reacting portion of the first and second reactive gases. For example of applying the above-mentioned ALD method, a process of forming an alumina (Al₂O₃) film using the conventional ALD is explained with reference to FIG. 1.

At a deposition temperature of about 370° C., tri-methyl-aluminum [Al(CH₃)₃, TMA] is introduced into the reaction chamber for the first period “t1” of about one second under the first pressure “CP1” of about 230 mTorr. Then, the introduction of TMA is stopped, and Ar gas is introduced into the reaction chamber for the second period “ct2” of about 14 seconds. The above-mentioned Ar gas prevents the TMA from being over-adsorbed on the silicon substrate, and discharges a residual non-reacting gas out of the reaction chamber.

Thereafter, a distilled water (DW) vapor is introduced into the reaction chamber for the third period “ct3” of about 1 second under the second pressure “CP2” of about 200 mTorr. Subsequently, the introduction of TMA is stopped, and Ar gas is introduced again into the reaction chamber for the fourth period “ct4” of about 14 seconds such that another residual non-reacting gas is discharged out of the reaction chamber.

After one cycle, specifically 30 seconds, of the above-mentioned process, obtained alumina film is just 0.3 nm in thickness. Therefore, to fabricate 10 nm alumina film, the above-mentioned cycle should be repeated for about 34 times. In other words, it takes about 1000 seconds to fabricate the 10 nm film by applying the ALD.

The above-mentioned processing time of the conventional ALD is much longer than that of the CVD. Since a lot of cluster systems are needed to compensate for the longer processing time, cost of fabricating thin films increases when the ALD is applied.

### SUMMARY OF THE INVENTION

Accordingly, the present invention is directed to a method of forming a thin film using an ALD that substantially obviates one or more of the problems due to limitations and disadvantages of the related art.

An object of the present invention is to provide a method of forming a thin film using an ALD having a short processing time.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

In order to achieve the above object, the preferred embodiment of the present invention provides a method of forming a thin film using an ALD. The method includes: a first step of disposing a silicon substrate in a reaction chamber; a second step of introducing a first reactive gas and a carrier gas into the reaction chamber during a first period such that the first reactive gas is chemically adsorbed on the silicon substrate, wherein the reaction chamber is set to a first pressure during the first period; a third step of introducing a second reactive gas into the reaction chamber during a second period such that the second reactive gas is chemically adsorbed on the silicon substrate and discharges a residual portion of the first reactive gas out of the reaction chamber, wherein the reaction chamber is set to a lower second pressure than the first pressure during the second period; and further introducing the second reactive gas into the reaction chamber for a third period such that the second reactive gas is further chemically adsorbed on the silicon substrate, wherein the reaction chamber is set to a higher third pressure than the first pressure during the third period.

A carrier gas is preferably further introduced into the reaction chamber during the second and third periods.

Preferably, the second to fourth steps are sequentially repeated at least two times.

In one aspect, the first reactive gas includes Ti element, and the second reactive gas includes nitrogen element such that TiN thin film is formed on the silicon substrate. Preferably, the first reactive gas is TiCl4, and the second reactive gas is NH3. At this point, a temperature of the reaction chamber is about 500° C., the first pressure of the first period is 0.04 to 0.06 Torr, the second pressure of the second period is 0.008 to 0.012 Torr, and the third pressure of the third period is 0.02 to 0.03 Torr. Preferably, the first period is 0.8 to 1.2 seconds, the second period is for 3 to 5 seconds, and the third period is 8 to 12 seconds.

In another aspect, the first reactive gas includes aluminum element, and the second reactive gas includes oxygen element such that alumina thin film is formed on the silicon substrate. Preferably, the first reactive gas is tri-methyl-aluminum, and the second reactive gas is distilled water. At this point, a temperature of the reaction chamber is about 350° C., the first pressure of the first period is 0.2 to 0.3 Torr, a second pressure of the second period is 0.04 to 0.06 Torr, and the third pressure of the third period is 0.2 to 0.3 Torr. Preferably, the first period is 0.8 to 1.2 seconds, the second period is 3.2 to 4.8 seconds, and the third period is 4 to 6 seconds.

It is to be understood that both the foregoing general description and the following detailed description are exemplary and explanatory and are intended to provide further explanation of the invention as claimed.

### BRIEF DESCRIPTION OF THE DRAWING

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a graph illustrating a method of forming a thin film using an ALD according to the related art;

FIG. 2 is a graph illustrating a method of forming a thin film using an ALD according to the preferred embodiment of the present invention; and

FIG. 3 is a process diagram illustrating the method of forming a thin film using an ALD according to the preferred embodiment of the present invention.

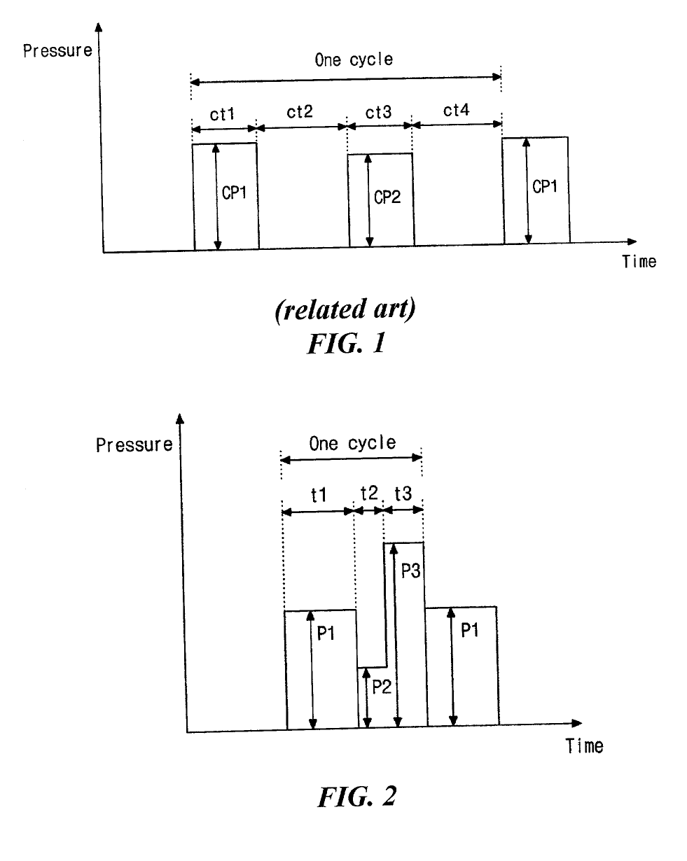

### DETAILED DESCRIPTION OF THE PREFERRED EMBODIMENTS

Reference will now be made in detail to the preferred embodiments of the present invention, examples of which are illustrated in the accompanying drawings.

### First Preferred Embodiment

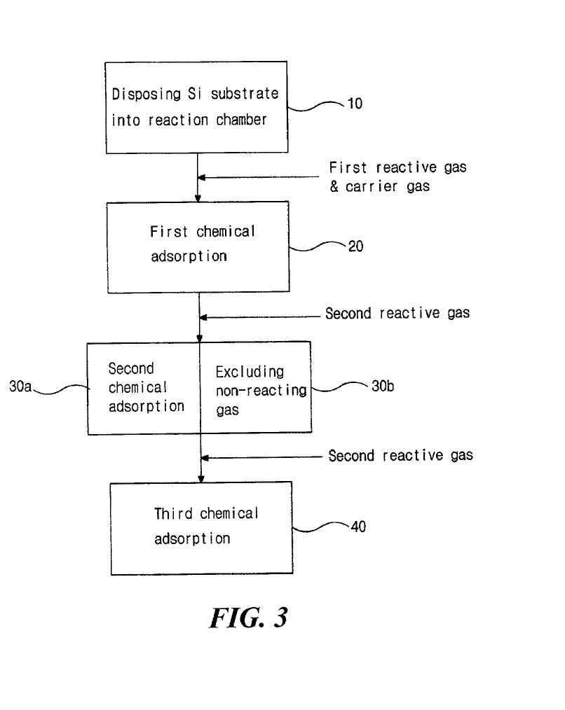

Now, a method of forming TiN thin film using an ALD, according the first preferred embodiment, is explained with reference to FIGS. 2 and 3.

For a first step 10, a silicon (Si) substrate having an oxide film thereon is disposed in a reaction chamber. The temperature of the reaction chamber is adjusted to 500° C. Then, for second step 20, a first reactive gas, preferably TiCl₄, and a carrier gas, preferably Ar, are introduced into the reaction chamber. At this point, the flow rate of TiCl₄ and Ar preferably has a range of 80 to 120 sccm (one sccm is one standard cubic centimeter of gas per minute, and one standard cubic centimeter of gas is measured at 25° C. and one standard atmosphere) such that the reaction chamber is set to a first pressure “P1” of 0.04 to 0.06 Torr during a first period “t1”. The first period is preferably 0.8 to 1.2 seconds. Under these conditions, TiCl₄ is chemically adsorbed on the silicon substrate during the first period “t1”. To minimize a needless physical adsorption, the above-mentioned chemical adsorption of the first reactive gas is performed under a minimum pressure as well as for a minimum time. The carrier gas, Ar, is an inert gas and serves to minimize a probability of a reaction between a residual gas that remains in the reaction chamber and a second reactive gas that will be introduced into the reaction chamber later. In addition, if the first reactive gas has some viscosity, the carrier gas serves to dilute the viscosity of the first reactive gas such that the first reactive gas is prevented from being adsorbed onto the reaction chamber.

After the first period “t1”, for the third step 30a and 30b, the second reactive gas, preferably NH₃, is introduced into the reaction chamber with a flow rate of 240 to 360 sccm such that the reaction chamber is set to a second pressure “P2” of 0.008 to 0.012 Torr, which is lower than the first pressure “P1” set by TiCl₄ and Ar. Under these conditions, nitrogen element of NH₃ is chemically adsorbed on the silicon substrate during a second period “t2” such that TiN thin film is formed. The second period “t2” is preferably 3 to 5 seconds. At this point, the second reactive gas further serves to discharge a residual TiCl₄ gas that still remains in the reaction chamber but was not chemically adsorbed on the silicon substrate.

Subsequently, for the fourth step 40, the second reactive gas, NH₃, is further introduced into the reaction chamber with the flow rate of 240 to 360 sccm such that the reaction chamber is set to a third pressure “P3” of 0.2 to 0.3 Torr, which is higher than the first pressure “P1” set by TiCl₄ and Ar. Under these conditions, nitrogen element of NH₃ is chemically adsorbed on the silicon substrate more densely during a third period “t3” of 8 to 12 seconds such that TiN thin film is further formed.

Meanwhile, a shower head, which is most widely used for a thermal chemical vapor deposition (TCVD), may be adopted for injecting the above-mentioned gases. In that case, a small quantity of impure particles are produced at an early state. The amount of impure particles, however, increases as a nozzle of the shower head repeatedly contacts the reactive gases. That is to say, as the nozzle repeatedly contacts the reactive gases, incomplete reactions occur such that the amount of impure particles increases. To avoid the above-mentioned problem of the conventional shower head, a multi-injector having a plurality of jet orifices is preferably adopted for injecting TiCl₄, Ar, and NH₃.

The above-mentioned process according to the first preferred embodiment takes 11.8 to 18.2 seconds for one cycle. During the one cycle of the process, TiN thin film of 1.2 to 1.8 nm in thickness is obtained. The obtained TiN thin film exhibits over 90% step coverage for a contact hole having a bottom diameter of 0.3 μm and a depth-to-diameter ratio (depth/diameter) of 3.8. In addition, a specific resistance of the obtained TiN thin film is about 130 μΩ.cm.

Meanwhile, if chlorine is included in a thin film, the included chlorine reacts with moisture in the atmosphere such that a strong acid HCl is formed. Since the strong acid HCl damages not only the thin film but also a metal line, which is generally formed on the thin film, a reliance of the metal line is deteriorated. The TiN thin film formed by applying the method according to the first preferred embodiment, however, has a lower chlorine density than a measuring limit when detected by a X-ray photoelectron spectroscopy (XPS). That is to say, the method according to the first preferred embodiment provides an improved reliance for the metal line, which will be formed on the thin film, such that a more minute metal line is applicable.

### Second Preferred Embodiment

Now, a method of forming alumina (Al₂O₃) film using an ALD, according the second preferred embodiment is explained with reference to FIGS. 2 and 3.

For a first step 10, a silicon (Si) substrate having an oxide film thereon is disposed in a reaction chamber, and the temperature of the reaction chamber is adjusted to 500° C. Then, for a second step 20, a first reactive gas, preferably TMA, and a carrier gas, preferably Ar, are introduced into the reaction chamber. At this point, the flow rate of TMA and Ar preferably has a range of 80 to 120 sccm such that the reaction chamber is set to a first pressure “P1” of 0.2 to 0.3 Torr during a first period “t1”. The first period “t1” is preferably 0.8 to 1.2 seconds. Under these conditions, TMA is chemically adsorbed on the silicon substrate during the first period “t1”.

Thereafter, for the third step 30a and 30b, the second reactive gas, preferably DIW, and Ar gas are introduced into the reaction chamber with a flow rate of 80 to 120 sccm such that the reaction chamber is set to a second pressure “P2”. The second pressure “P2” preferably has a range of 0.04 to 0.06 Torr, which is lower than the first pressure “P1” set by TMA and Ar. Under these conditions, oxygen element of DIW is chemically adsorbed on the silicon substrate during a second period “t2” of 3.2 to 4.8 seconds such that alumina thin film is formed. At this point, the inert gas Ar serves to discharge a residual TMA that still remains in the reaction chamber but was not chemically adsorbed on the silicon substrate. That is to say, the inert gas Ar collides with the residual TMA physically adsorbed on the alumina thin film such that the residual TMA is efficiently discharged.

Subsequently, for the fourth step 40, the second reactive gas DIW and the inert gas Ar are further introduced into the reaction chamber with the flow rate of 80 to 120 sccm such that the reaction chamber is set to a third pressure “P3”. The third pressure “P3” preferably has a range of 0.2 to 0.3 Torr, which is higher than the first pressure “P1” set by TMA and Ar. Under these conditions, oxygen element of DIW is chemically adsorbed on the silicon substrate more densely during a third period “t3” of 4 to 6 seconds such that alumina thin film is further formed. At this point, the inert gas Ar serves to prevent or minimize the physical adsorption of the DIW. Like the first preferred embodiment, a multi-injector having a plurality of jet orifices is preferred for injecting TMA, Ar, and DIW.

The above-mentioned process according to the second preferred embodiment takes 8 to 12 seconds for one cycle. During the one cycle of the process, alumina thin film of 0.17 to 0.25 nm in thickness is obtained. The obtained alumina thin film exhibits over 90% step coverage for a contact hole having a bottom diameter of 0.3 μm and a depth-to-diameter ratio (depth/diameter) of 3.8. In addition, a reflective index of the obtained alumina thin film is 1.6 and 1.62 at 633 nm wavelength with respect to a silicon substrate and a silicon oxide (SiO₂) film, respectively. Furthermore, the alumina thin film obtained by applying the method according to the second preferred embodiment has a lower carbon density than a measuring limit when detected by a X-ray photoelectron spectroscopy (XPS). That is to say, the alumina thin film fabricated by applying the method according the second preferred embodiment has an improved density and an improved electric quality.

As previously explained, at least 0.17 nm alumina thin film is obtained after one cycle, specifically 12 seconds, of the above-mentioned process. Therefore, to fabricate 10 nm alumina thin film, the above-mentioned cycle should be repeated for about 60 times. In other words, it takes about 720 seconds to fabricate the 10 nm alumina thin film by applying the method according to the second preferred embodiment. Compared with the conventional method by which it takes 1000 seconds to fabricate the 10 nm alumina thin film, the inventive method provides a superior productivity.

It will be apparent to those skilled in the art that various modifications and variation can be made in the method of manufacturing a thin film transistor of the present invention without departing from the spirit or scope of the invention. Thus, it is intended that the present invention cover the modifications and variations of this invention provided they come within the scope of the appended claims and their equivalents.

What is claimed is:

1. A method of fabricating a thin film using an atomic layer deposition, the method comprising:
a first step of disposing a silicon substrate in a reaction chamber;
a second step of introducing a first reactive gas and a carrier gas into the reaction chamber during a first period such that the first reactive gas is chemically adsorbed on the silicon substrate, wherein the reaction chamber is set to a first pressure during the first period;
a third step of introducing a second reactive gas into the reaction chamber during a second period such that the second reactive gas is chemically adsorbed on the silicon substrate and discharges a residual portion of the first reactive gas out of the reaction chamber, wherein the reaction chamber is set to a lower second pressure than the first pressure during the second period; and
further introducing the second reactive gas into the reaction chamber for a third period such that the second reactive gas is further chemically adsorbed on the silicon substrate, wherein the reaction chamber is set to a higher third pressure than the first pressure during the third period.

2. The method of claim 1, wherein a carrier gas is further introduced into the reaction chamber during the first period.

3. The method of claim 1, wherein a carrier gas is further introduced into the reaction chamber during the second period.

4. The method of claim 1, wherein the second to fourth steps are sequentially repeated at least two times.

5. The method of claim 1, wherein the first reactive gas includes Ti element, and the second reactive gas includes nitrogen element such that TiN thin film is formed on the silicon substrate.

6. The method of claim 5, wherein the first reactive gas is TiCl₄, and the second reactive gas is NH₃.

7. The method of claim 6, wherein a temperature of the reaction chamber is about 500° C., the first pressure of the first period is 0.04 to 0.06 Torr, the second pressure of the second period is 0.008 to 0.012 Torr, and the third pressure of the third period is 0.02 to 0.03 Torr.

8. The method of claim 7, wherein the first period is 0.8 to 1.2 seconds, the second period is for 3 to 5 seconds, and the third period is 8 to 12 seconds.

9. The method of claim 1, wherein the first reactive gas includes aluminum element, and the second reactive gas includes oxygen element such that alumina thin film is formed on the silicon substrate.

10. The method of claim 9, wherein the first reactive gas is tri-methyl-aluminum, and the second reactive gas is distilled water.

11. The method of claim 10, wherein a temperature of the reaction chamber is about 350° C., the first pressure of the first period is 0.2 to 0.3 Torr, a second pressure of the second period is 0.04 to 0.06 Torr, and the third pressure of the third period is 0.2 to 0.3 Torr.

12. The method of claim 11, wherein the first period is 0.8 to 1.2 seconds, the second period is 3.2 to 4.8 seconds, and the third period is 4 to 6 seconds.
